(19) United States
(12) Patent Application Publication
(10) Pub. No.: US 2007/0045652 A1
(43) Pub. Date: Mar. 1, 2007

(54) Semiconductor device

(75) Inventors: Hajime Kurata, Kawasaki (JP); Kunihiko Gotoh, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/362,182

(22) Filed: Feb. 27, 2006

(30) Foreign Application Priority Data
Aug. 30, 2005 (JP) 2005-249914

(51) Int. Cl. H01L 33/00

(52) U.S. Cl. 257/103

(57) ABSTRACT

A semiconductor device is provided that includes a semiconductor substrate, a first resistance element on a semiconductor substrate, a capacitance element over the first resistance element, and an insulating layer between the first resistance element and the capacitance element.

### CROSS-REFERENCE TO RELATED APPLICATIONS

This application is based upon and claims the benefit of priority from the prior Japanese Patent Application No. 2005-249914, filed on Aug. 30, 2005, the entire contents of which are incorporated herein by reference.

### BACKGROUND OF THE INVENTION

1. Field of the Invention

The present invention relates to semiconductor devices.

2. Description of the Related Art

As to semiconductor devices having resistance elements and capacitance elements, the following Patent Documents 1-3 have been disclosed. Patent Document 1 describes an input-protection circuit device of a semiconductor integrated circuit in which an input pad is coupled to a capacitor through a resistor. Patent Document 2 also describes a semiconductor device that includes, a first polysilicon layer formed along the surface of a trench, and a second polysilicon layer deposited on an insulating layer above the first polysilicon layer, where the second polysilicon layer fills the trench and is used as a resistor. Patent Document 3 also describes a semiconductor analog integrated circuit in which resistors and capacitors are formed.

[Patent Document 1] Japanese Patent Application Laid-open No. 2000-12778

[Patent Document 2] Japanese Patent Application Laid-open No. Hei 11-330375

[Patent Document 3] Japanese Patent Application Laid-open No. Hei 5-259416

In Patent Documents 1 and 3, because the resistor and the capacitor are formed in separate places, it is difficult to miniaturize the semiconductor device. In Patent Document 2, the inner side of the trench is a resistor, the outer side thereof is a capacitor, and a configuration is made in which the resistor and the capacitor are integrated, and therefore the configuration cannot be applied to a circuit configuration in which the resistor and the capacitor are isolated to each other through an insulating layer.

### SUMMARY OF THE INVENTION

An object of the present invention is to miniaturize the size of semiconductor devices that include resistors and capacitors.

According to an aspect of the present invention, there is provided a semiconductor device that includes: a semiconductor substrate; a first resistance element on the semiconductor substrate; a capacitance element over the first resistance element; and an insulating layer between the first resistance element and the capacitance element.

### BRIEF DESCRIPTION OF THE DRAWINGS

FIG. 1 is a sectional view of the semiconductor device according to a first embodiment of the present invention.

FIG. 2 is the plan view of the semiconductor device of FIG. 1.

FIGS. 3A to 3F are the sectional views of the semiconductor device showing a method of manufacturing the semiconductor device of FIG. 1.

FIG. 4 is a sectional view of the semiconductor device according to a second embodiment of the present invention.

FIG. 5 is a sectional view of the semiconductor device showing a method of manufacturing the semiconductor device of FIG. 4.

FIG. 6 is a view showing an example of layout of a semiconductor integrated circuit (semiconductor device).

FIG. 7 is a view showing an example of layout of the semiconductor integrated circuit (semiconductor device) according to a third embodiment of the present invention.

### DETAILED DESCRIPTION OF THE PREFERRED EMBODIMENTS

### First Embodiment

As the miniaturization and portability of systems have been progressing, there is a need for semiconductor integrated circuits that operate at low power consumption. The specific example includes applications of IC cards and ID chips (RFID tags), which are generally not allowed to have a battery as the power supply, and in the semiconductor integrated circuits used therein, the electric power is obtained from energy of the electromagnetic wave to be irradiated for the access, and a wide range of communication area can be realized by low power consumption. On the other hand, as to the circuits for such an application, low cost is strongly demanded, and thus the reduction in size of semiconductor chips is needed.

In the applications of IC cards and ID chips, a smoothing capacitor to be used for stabilizing the power supply is large. In the process having the smoothing capacitor and a ferroelectric memory (FeRAM) mixed together, the ferroelectric capacitor with a large capacitance can be used as the smoothing capacitor, and therefore it is advantageous in terms of the reduction in chip size. On the other hand, in such an application, for the purpose of low power consumption, the consumed electric current needs to be reduced using large resistors (resistors with high resistance), and the area of the resistors used in the circuit becomes relatively large, thereby preventing the chip size reduction. Namely, if the resistors and capacitors are arranged in different places in two dimensions on a semiconductor substrate like a general semiconductor integrated circuit, the area which such resistance elements and capacitance elements occupy is large, therefore the reduction in chip size cannot be attained and the cost reduction becomes difficult. In an analog circuit, it is considered that passive elements, such as a resistor and a capacitance, are arranged in three dimensions, thereby to reduce the chip size. Even in such a semiconductor device, if the positions of the resistor and the capacitor are shifted to each other in two dimensions, an effect of reducing the chip size can not be expected in the analog circuit of low power consumption. Hereinafter, a first embodiment of the present invention for solving this problem will be described.

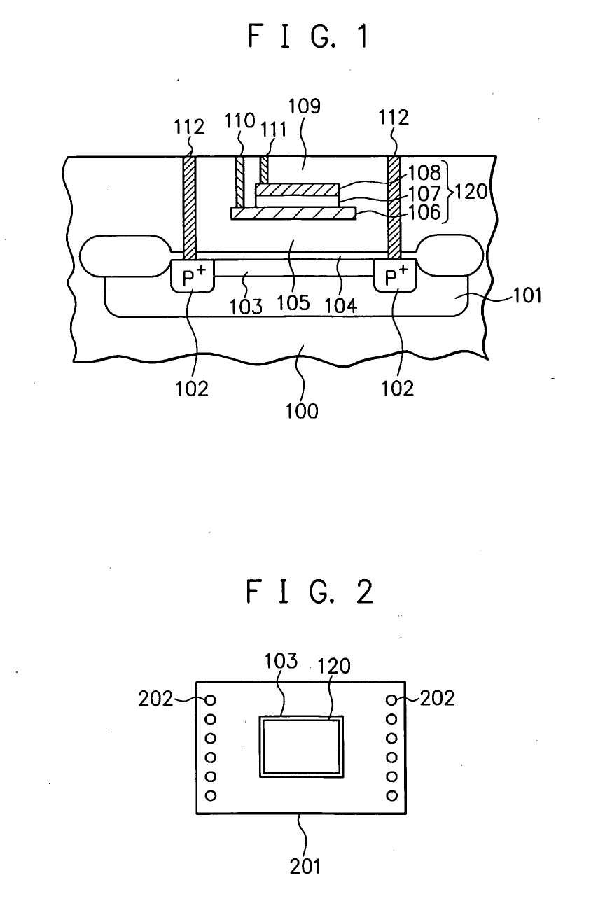

FIG. 1 is a sectional view of the semiconductor device according to a first embodiment of the present invention. This semiconductor device is, for example, an IC (Integrated Circuit) card or an RFID (Radio Frequency Identification) tag.

A semiconductor substrate 100 is a silicon substrate, for example. An N type well 101 is formed in the silicon substrate 100. A P type diffusion layer 103 is formed in the N type well 101. The diffusion layer 103 forms a resistor. P⁺ type contact regions 102 are formed at both ends of the diffusion layer resistor 103. Above the diffusion layer resistor 103, a lower electrode 106 is formed via insulating layers 104 and 105. The insulating layers 104 and 105 are made of silicon oxide, for example. A dielectric material 107 is formed on the lower electrode 106, and moreover, an upper electrode 108 is formed thereon. A capacitor 120 comprises the lower electrode 106, the dielectric material 107, and the upper electrode 108. The capacitor 120 is a ferroelectric capacitor. The lower electrode 106 is made of Pt (platinum), for example. The ferroelectric material 107 is PZT (lead zirconate titanate). The upper electrode 108 is made of IrO₂ (iridium dioxide), for example. An insulating layer 109 is formed on the upper electrode 108. The insulating layer 109 is made of silicon oxide, for example. A plug 110 is connected to the lower electrode 106 through a contact hole. A plug 111 is connected to the upper electrode 108 through a contact hole. A plug 112 is connected to a contact region 102 through a contact hole. The plugs 110-112 are made of W (tungsten), for example. The plugs 110 and 111 are the terminals for the capacitor 120. The plug 112 is the terminal for the resistor 103.

The resistor 103 is arranged on the semiconductor substrate 100. The insulating layers 104 and 105 are arranged in between the resistor 103 and the capacitor 120. The plug 112 is connected to the resistor 103 through a contact hole. The resistor 103 and the capacitor 120 can be arranged across a large area in regions other than the plug 112. Moreover, no transistor is arranged under the capacitor 120. In this way, the capacitor 120 can be formed on a flat face of the semiconductor substrate.

FIG. 2 is a plan view of the semiconductor device of FIG. 1. A semiconductor device (semiconductor chip) 201 comprises a pad 202, for example. The capacitor 120 is arranged as to overlap above the resistor 103. In this embodiment, the resistor 103 and the capacitor 120 are stacked as to overlap in three dimensions. Because the resistor 103 and the capacitor 120 can be arranged as to overlap in the depth direction of the semiconductor substrate, the semiconductor device (semiconductor chip) can be miniaturized. Here, a diffusion layer of the semiconductor substrate, with which a high resistance is easily realized, is used as the resistor 103. Such structure has few manufacturing problems as compared with a stacked structure of a transistor and a capacitor used in a DRAM memory cell, and it has a large effect in the chip size reduction especially in analog circuits of low power consumption that need a large number of resistors and capacitors. Especially in semiconductor integrated circuits used for portable appliances, in which low power consumption is required, the cost reduction due to the chip size reduction can be attained.

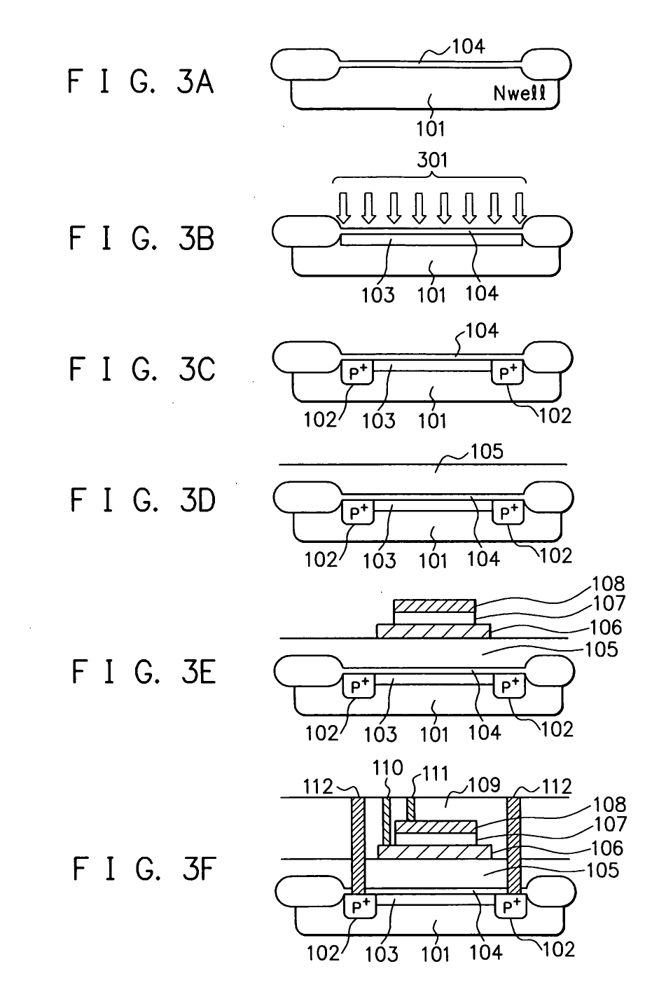

FIGS. 3A to 3F are sectional views of the semiconductor device showing the method of manufacturing the semiconductor device of FIG. 1. Taking a case where the ferroelectric material is used, as an example, the method of manufacturing a semiconductor device having a three dimensional configuration of a resistor and a capacitor will be described.

First, as shown in FIG. 3A, a step of isolating the semiconductor substrate is carried out. The N type well 101 is formed on the semiconductor substrate (silicon substrate). Next, only a part of the surface of the semiconductor substrate is selectively thermally-oxidized by LOCOS (Local Oxidation of Silicon) to form the silicon oxide 104. Thereby, a plurality of elements on the semiconductor substrate can be electrically isolated.

Next, as shown in FIG. 3B, P type impurities 301 are ion implanted to the active region 103, thereby forming the resistor 103 that uses the P type diffusion layer.

Next, as shown in FIG. 3C, P type impurities are ion implanted only to the regions 102 using a mask, thereby forming the P⁺ type contact regions 102.

Next, as shown in FIG. 3D, the interlayer insulating layer 105 is deposited on the surface of the semiconductor substrate, and this interlayer insulating layer 105 is planarized by CMP (Chemical Mechanical Polishing). The interlayer insulating layer 105 is made of silicon oxide, for example.

Next, as shown in FIG. 3E, the lower electrode 106 of the capacitor is deposited on the interlayer insulating layer 105 by sputtering. The lower electrode is made of Pt, for example. Next, the ferroelectric material 107 is deposited on the lower electrode 106 by sputtering. The ferroelectric material 107 is PZT, for example.

Next, the upper electrode 108 of the capacitor is deposited on the ferroelectric material 107 by sputtering. The upper electrode 108 is made of IrO₂, for example.

Next, the upper electrode 108 is patterned into a predetermined shape by photolithography and etching. Then, the ferroelectric material 107 is patterned into a predetermined shape by etching. Subsequently, the lower electrode 106 is patterned into a predetermined shape by photolithography and etching. The lower electrode 106, the ferroelectric material 107, and the upper electrode 108 compose the ferroelectric capacitor 120. The ferroelectric capacitor 120 is formed as to overlap above the diffusion layer resistor 103.

Next, as shown in FIG. 3F, the interlayer insulating layer 109 is deposited on the surface of the semiconductor substrate, and the interlayer insulating layer 109 is planarized by CMP. The interlayer insulating layer 109 is made of silicon oxide, for example. Then, the contact holes, that lead to the lower electrode 106, the upper electrode 108, and the resistor contact regions 102, are opened by etching. Subsequently, these contact holes are buried with the plugs 110-112 and planarized. The plugs 110-112 are made of W, for example.

Then, Al (aluminum) is deposited on the surface of the semiconductor substrate by sputtering. Then, this Al is etched into a predetermined pattern, thereby forming a first layer of metal wiring. Subsequently, through the typical wiring steps, a semiconductor integrated circuit (semiconductor device) with a structure in which the diffusion layer resistor 103 and the ferroelectric capacitor 120 are stacked is completed.

As described above, according to this embodiment, by arranging the capacitor 120 as to overlap above the resistor 103, the size of the semiconductor device can be miniaturized and the cost can be reduced. Moreover, because the resistor 103 can be made a resistor with high resistance, a semiconductor device of low power consumption can be realized. Moreover, by using a ferroelectric capacitor as the capacitor 120, the area which the capacitor 120 occupies can be reduced and the size of the semiconductor device can be reduced.

### Second Embodiment

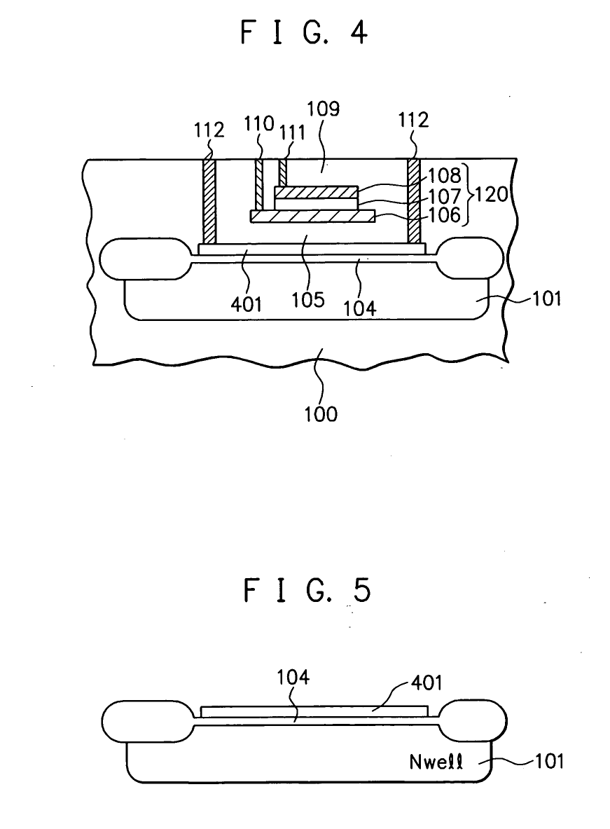

FIG. 4 is a sectional view of the semiconductor device according to a second embodiment of the present invention. The embodiment of FIG. 4 differs from the first embodiment of FIG. 1 in that a resistor 401 is formed in place of the resistor 103 and the contact regions 102. Hereinafter, the points that this embodiment differs from the first embodiment will be described. On other points, this embodiment is the same as the first embodiment.

A resistor 401 is made of polysilicon (polycrystal silicon) deposited on the insulating layer 104 on the semiconductor substrate. The plugs 112 are connected to both ends of the resistor 401. Like the first embodiment, the capacitor 120 is arranged as to overlap above the resistor 401. The insulating layer 105 is arranged in between the resistor 401 and the capacitor 120.

Then, the method of manufacturing the semiconductor device of FIG. 4 will be described. First, the step shown in FIG. 3A is carried out like in the first embodiment. Then, as shown in FIG. 5, the polysilicon 401 is deposited on the surface of the semiconductor substrate by CVD (Chemical Vapor Deposition). The polysilicon 401 is patterned into a predetermined shape by photolithography and etching. This polysilicon 401 forms the resistor. Subsequently, the steps shown in FIGS. 3D to 3F are carried out. However, the plugs 112 are connected to the both ends of the resistor 401.

Also in this embodiment, like the first embodiment, by arranging the capacitor 120 as to overlap above the resistor 401, the size of the semiconductor device can be miniaturized and the cost can be reduced. Moreover, because the resistor 401 can be made a resistor with high resistance, a semiconductor device of low power consumption can be realized. Moreover, by using a ferroelectric capacitor as the capacitor 120, the area which the capacitor 120 occupies can be reduced and the size of the semiconductor device can be reduced.

### Third Embodiment

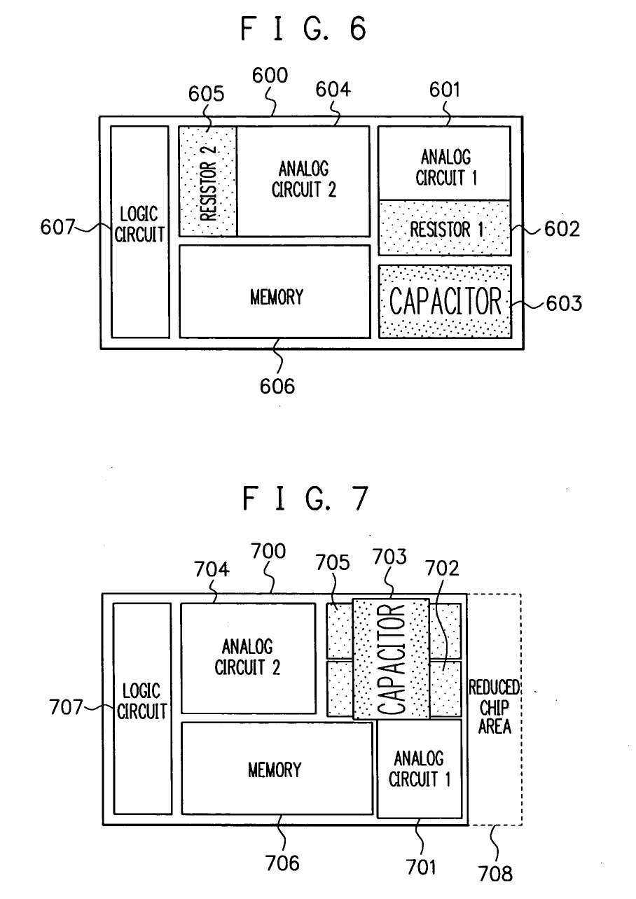

FIG. 6 is a view showing an example of layout of a semiconductor integrated circuit (semiconductor device). A semiconductor integrated circuit 600 comprises a first analog circuit 601, a first resistor 602, a capacitor 603, a second analog circuit 604, a second resistor 605, a memory 606, and a logic circuit 607.

In the analog circuits 601 and 604 of low power consumption, large resistors are needed mainly in a bias circuit in order to reduce the consumed electric current. The first analog circuit 601 is, for example, a band gap reference circuit (BGR). The second analog circuit 604 is, for example, a voltage controlled oscillator circuit (VCO). Each of the analog circuits 601 and 604 comprises a bias circuit. In the bias circuit, large resistors are used for generating the bias voltages or the bias currents. The first resistor 602 is connected to the bias circuit in the first analog circuit 601. The second resistor 605 is connected to the bias circuit in the second analog circuit 604. The capacitor 603 is a smoothing capacitor for stabilizing the power supply of the semiconductor integrated circuit 600. If the resistor 602, 605 and the smoothing capacitor 603 are arranged at separate places in two dimensions, the layout efficiency is low and the size of the semiconductor chip 600 becomes large.

FIG. 7 is a view showing an example of layout of the semiconductor integrated circuit (semiconductor device) according to a third embodiment of the present invention. A semiconductor integrated circuit 700 comprises a first analog circuit 701, a first resistor 702, a capacitor 703, a second analog circuit 704, a second resistor 705, a memory 706, and a logic circuit 707. The memory 706 and the logic circuit 707 are digital circuits. The semiconductor integrated circuit 700 has the analog circuits 701, 704, and the digital circuit 706, 707 mixed together.

This embodiment employs the semiconductor integrated circuit according to the first or second embodiment. The first resistor 702 and the second resistor 705 are arranged on the semiconductor substrate. The capacitor 703 is arranged as to overlap above the first resistor 702 and the second resistor 705. An insulating layer is arranged in between the resistor 702, 705, and the capacitor 703.

In the analog circuits 701 and 704 of low power consumption, large resistors are needed mainly in the bias circuit in order to reduce the consumed electric current. The first analog circuit 701 is, for example, a band gap reference circuit (BGR). The second analog circuit 704 is, for example, a voltage controlled oscillator circuit (VCO). Each of the analog circuits 701 and 704 comprises a bias circuit. In the bias circuit, large resistors are used for generating the bias voltages or the bias currents. The first resistor 702 is connected to the bias circuit in the first analog circuit 701. The second resistor 705 is connected to the bias circuit in the second analog circuit 704. The capacitor 703 is a smoothing capacitor for stabilizing the power supply of the semiconductor integrated circuit 700.

Because the resistor 702, 705 and the smoothing capacitor 703 are arranged as to overlap, the layout efficient is high and the size of the semiconductor chip 700 can be reduced. In the semiconductor integrated circuit 700 of FIG. 7, as compared with the semiconductor integrated circuit 600 of FIG. 6, the area of a chip region denoted by reference numeral 708 can be cut down to reduce the chip size.

As described above, in this embodiment, the resistors 702 and 705 used for the analog circuits 701 and 704 are placed adjacently and put together in a portion on the semiconductor integrated circuit 700, thereby obtaining a two dimensional open space of a certain level of size. Then, the ferroelectric capacitor 703 used as the smoothing capacitor is stacked above these resistors 702 and 705, thereby allowing the size of the semiconductor chip 700 to be reduced.

Note that any one of the above embodiments just shows an example of the implementation in carrying out the present invention, and the technical scope of the present invention should not be interpreted limitedly by these embodiments. Namely, the present invention can be carried out in various forms without departing from the technical scope and spirit, or from the principal features thereof.

Arranging the capacitance element as to overlap above the first resistance element allows the size of the semiconductor device to be miniaturized and the cost to be reduced. Moreover, because the resistor can be made a resistor with high resistance, a semiconductor device of low power consumption can be realized.

What is claimed is:

1. A semiconductor device, comprising:
a semiconductor substrate;
a first resistance element on the semiconductor substrate;
a capacitance element over the first resistance element; and
an insulating layer between the first resistance element and the capacitance element.

2. The semiconductor device according to claim 1, further comprising a plug connected to the first resistance element through a contact hole, wherein the first resistance element and the capacitance element are in regions other than the plug.

3. The semiconductor device according to claim 1, wherein no transistor is under the capacitance element.

4. The semiconductor device according to claim 1, wherein the first resistance element is the one using a diffusion layer of the semiconductor substrate.

5. The semiconductor device according to claim 1, wherein the first resistance element is the one using a polysilicon deposited on the semiconductor substrate.

6. The semiconductor device according to claim 1, wherein the capacitance element is a ferroelectric capacitor.

7. The semiconductor device according to claim 1, further comprising a second resistance element on the semiconductor substrate, wherein the capacitance element is over the first and the second resistance elements.

8. The semiconductor device according to claim 1, further comprising a first analog circuit connected to the first resistance element.

9. The semiconductor device according to claim 8, further comprising:
a second resistance element on the semiconductor substrate; and
a second analog circuit connected to the second resistance element,
wherein the capacitance element is over the first and the second resistance elements.

10. The semiconductor device according to claim 8, further comprising a digital circuit.

11. The semiconductor device according to claim 8, wherein the first analog circuit comprises a bias circuit that generates bias voltages or bias currents using the first resistance element.

12. The semiconductor device according to claim 8, further comprising a plug connected to the first resistance element through a contact hole, wherein the first resistance element and the capacitance element are in regions other than the plug.

13. The semiconductor device according to claim 8, wherein no transistor is under the capacitance element.

14. The semiconductor device according to claim 8, wherein the first resistance element is the one using a diffusion layer of the semiconductor substrate.

15. The semiconductor device according to claim 8, wherein the first resistance element is the one using a polysilicon deposited on the semiconductor substrate.

16. The semiconductor device according to claim 8, wherein the capacitance element is a ferroelectric capacitor.

17. The semiconductor device according to claim 1, wherein the capacitance element, the insulating layer, and the resistance element are put in direct contact to each other.
